(19) United States
(12) Patent Application Publication
(10) Pub. No.: US 2009/0020408 A1
(43) Pub. Date: Jan. 22, 2009

(54) Substrate Processing Method and Substrate Processing Apparatus

(75) Inventors: Tsukasa Yashima, Imizu-shi (JP); Shigeki Nogami, Toyama-shi (JP); Hiroshi Ekko, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 12/087,729

(22) PCT Filed: Jul. 25, 2007
(86) PCT No.: PCT/JP2007/064541

§ 371 Date: Jul. 14, 2008

(30) Foreign Application Priority Data
Aug. 11, 2006 (JP) 2006-219678

(51) Int. Cl. H01L 21/3065

(52) U.S. Cl. 204/157.15; 204/229.8

(57) ABSTRACT

A substrate processing method that achieves enhancement in productivity by making it possible to confirm the end point in the ashing process precisely is provided. The substrate processing method includes: detecting emission intensity; calculating an amount of variance in emission intensity that has been detected; detecting an end point from the calculated amount of variance in emission intensity; making a comparison between the detected end point and a predetermined time; and displaying a result of the comparison.

### TECHNICAL FIELD

The present invention relates to a processing method of a substrate used in a semiconductor device or the like, and more particularly, to a substrate processing method suitable to perform ashing on the substrate surface using a plasma and a substrate processing apparatus.

### BACKGROUND ART

Generally, when a semiconductor device or the like is manufactured, a photoresist is applied on the wafer surface and a resist pattern is formed on the wafer surface by transferring a pattern formed on the photomask. Subsequently, processing to form a fine pattern by selectively etching the wafer surface or to selectively implant an impurity necessary for forming an embedded electrode is performed according to the resist pattern. Thereafter, in order to remove the photoresist that has become unnecessary, removal by means of ashing using an oxygen plasma, so-called an ashing process, is performed (Patent Document 1).

Regarding the ashing process, there is a technique to detect that all the resist on the wafer has been ashed (end point) from the magnitude of an amount of variance in emission intensity by detecting emission intensity of a plasma using a photodetector.

Patent Document 1: JP-A-7-153748

### DISCLOSURE OF THE INVENTION

### Problems that the Invention is to Solve

According to the technique described above, however, even in a case where an accidental variance is detected in an amount of variance in emission intensity before all the resist on the wafer is removed, such a variance is erroneously detected as the end point and the ashing process is terminated. Hence, there is a risk that a wafer from which the resist has not been completely removed, that is, an inferior article, is transported to the downstream processing.

The invention has an object to provide a processing method of a substrate that solves the problems in the related art discussed above in achieving enhancement in productivity by making it possible to confirm the end point of the ashing process precisely.

### Means for solving the problems

The invention is a substrate processing method, including: detecting emission intensity; calculating an amount of variance in emission intensity that has been detected; detecting an end point from the calculated amount of variance in emission intensity; making a comparison between the detected end point and a predetermined time; and displaying a result of the comparison.

### ADVANTAGE OF THE INVENTION

According to the invention, because the method includes the step of making a comparison between the detected end point and the predetermined time and the step of displaying the result of the comparison, the end point can be confirmed precisely. It is thus possible to achieve enhancement in productivity by preventing the process from being terminated due to an erroneous detection of the end point.

### Industrial Applicability

### BRIEF DESCRIPTION OF THE DRAWINGS

FIG. 1 is a plan view of a substrate processing apparatus according to one embodiment of the invention.

FIG. 2 is a longitudinal cross section of an ashing processing apparatus according to one embodiment of the invention.

FIG. 3 is a cross section taken on line A-A of FIG. 2 and showing the ashing processing apparatus according to one embodiment of the invention.

FIG. 4 is a block diagram used to describe the peripheral structure of a controller in the ashing processing apparatus according to one embodiment of the invention.

FIG. 5 is a table used to describe recipe setting data for an ashing process according to one embodiment of the invention.

FIG. 6 is a graph showing emission intensity and an amount of variance in emission intensity used by the controller in the ashing processing apparatus according to one embodiment of the invention, and FIG. 6A shows a normal time and FIG. 6B shows an abnormal time.

FIG. 7 is a flowchart detailing an end point detection process performed by the ashing processing apparatus according to one embodiment of the invention.

### DETAILED DESCRIPTION OF THE INVENTION

200: ashing processing apparatus
215: emission intensity measuring instrument
232: controller
232a: CPU
232d: calculation portion
232e: detection portion
234a: display screen

### BEST MODE FOR CARRYING OUT THE INVENTION

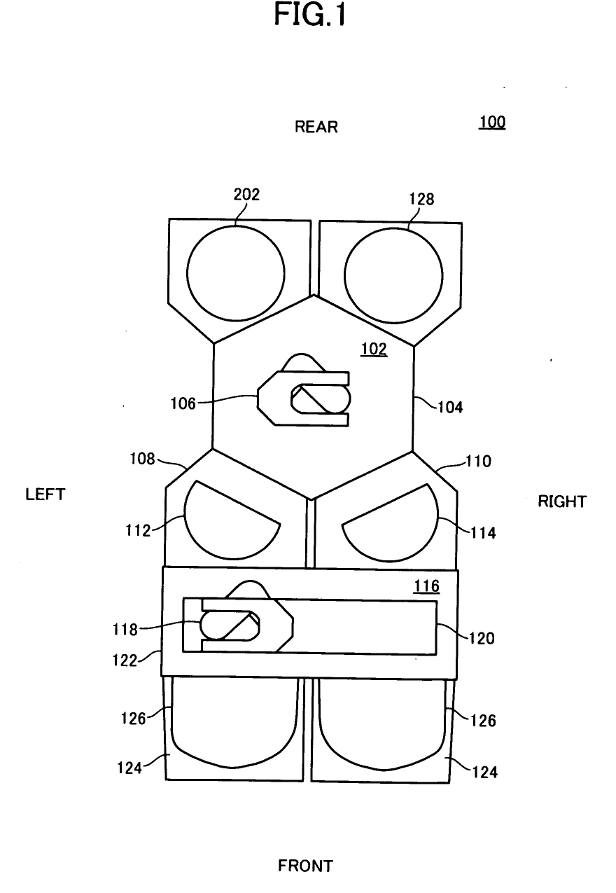

Initially, a substrate processing apparatus 100 to which a processing method of the invention is applied will be described on the basis of FIG. 1.

Indications of front, rear, right and left in FIG. 1 correspond, respectively, to the front, rear, right, and left in the following description.

The substrate processing apparatus 100 uses an FOUP (Front Opening Unified Pod) as a carrier to transport a substrate, such as a wafer.

As is shown in FIG. 1, the substrate processing apparatus 100 includes a first transfer chamber 102 as a first transportation chamber formed to have a structure that can withstand a pressure lower than atmospheric pressure (negative pressure), such as a vacuum state. A housing 104 of the first transfer chamber 102 is hexagonal when viewed in a plane and formed in the shape of a box that is closed at the both upper and lower ends. A first wafer transfer machine 106 that transfers a wafer at a negative pressure is installed in the first transfer chamber 102.

A first load lock chamber 108 as a carrying-in spare chamber and a second load lock chamber 110 as a carrying-out spare chamber are coupled, respectively, to the two side walls positioned on the front side among the six side walls of the housing 104, via gate valves (not shown), and each chamber is formed to have a structure that can withstand a negative pressure. Further, a substrate platform 112 for carrying-in chamber is installed in the first load lock chamber 108 and a substrate platform 114 for carrying-out chamber is installed in the second load lock chamber 110.

A second transfer chamber 116 as a second transportation chamber used almost at atmospheric pressure is coupled to the front side of the first load lock chamber 108 and the second load lock chamber 110 via gate valves (not shown). A second wafer transfer machine 118 that transfers a wafer is installed in the second transfer chamber 116. The second wafer transfer machine 118 is moved so as to reciprocate in the right-left direction by a linear actuator 120.

A housing 122 of the second transfer chamber 116 is provided with a wafer carrying-in and carrying-out port (not shown) through which a wafer is carried in or carried out from the second transfer chamber 116 and a pod opener (not shown). The pod opener allows a wafer to be taken out and placed in the pod by opening and closing the cap of a pod 126 mounted on an IO stage 124. The pod 126 is mounted on and demounted from the IO stage 124 by an RGV (Rail Guided Vehicle) (not shown).

A process chamber 202 as a first process furnace that performs a desired process on a wafer and a process chamber 128 as a second process furnace are adjacently coupled to the two side walls positioned on the rear side among the six side walls of the housing 104.

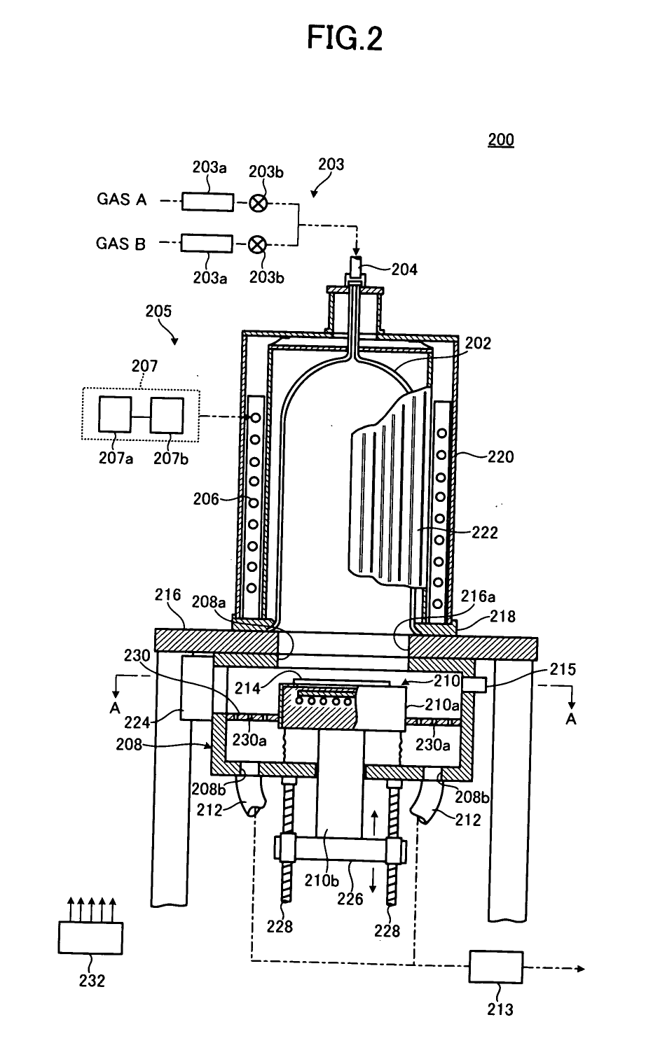

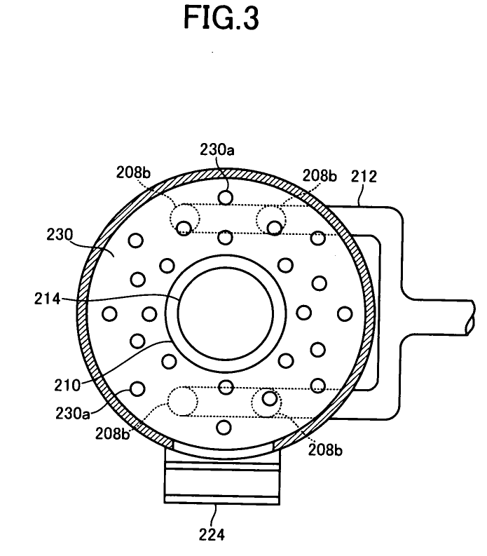

The process chamber 202 used in an ashing processing apparatus 200 will now be described on the basis of FIG. 2 and FIG. 3.

The configuration of the process chamber 202 as the first process room in the substrate processing apparatus 100 will be described for concrete and clear descriptions. It should be noted, however, that the same applies to the configurations of the other process rooms.

As is shown in FIG. 2, the ashing processing apparatus 200 has the process chamber 202 described above, a gas introduction channel 204, a plasma generator 205, a processing chamber 208, a wafer holder 210, and gas discharge channels 212. The process chamber 202 is made of, for example, high-purity quartz glass. It is formed in a cylindrical shape with an almost dome-shaped apex and configured in such a manner that the pressure in the interior can be reduced. A fine tube for introducing a gas for plasma generation is provided integrally with the process chamber 202 at the center of the apex. The gas introduction channel 204 is connected to the fine tube provided to the process chamber 202 so as to introduce a process gas, such as a gas for plasma generation, inside the chamber 202. A gas supply device 203 is connected to the gas introduction channel 204. The gas supply device 203 has MFCs (Mass Flow Controllers) 203a, valves 203b, and gas supply sources (not shown), and it supplies process gases A and B, such as a raw material gas and a purge gas, to the gas introduction channel 204. The processing chamber 208 is provided continuously with the process chamber 202 below the process chamber 202. The wafer holder 210 is installed inside the processing chamber 208 to hold a wafer 214 carried therein in an almost horizontal posture. The gas discharge channels 212 are provided in the lower portion of the processing chamber to discharge a gas inside the processing chamber 208.

The ashing processing apparatus 200 is assembled using a frame 216 provided with an almost horizontal base. The process chamber 202 is mounted on the base of the frame 216 with the axial line thereof oriented in the vertical direction. The process chamber 202 can take various forms in terms of outward appearance. It is formed in such a manner that at least the bottom surface is open and the periphery of the bottom surface having a larger diameter is locked with a flange 218 that fits onto the process chamber 202.

The plasma generator 205 has a high-frequency resonant coil 206 and a high-frequency power supply 207. By taking power to be applied thereon, the intensity of the magnetic field, or the outside shape of the apparatus into account, the high-frequency resonant coil 206 is formed to have an effective thickness of about 50 to 300 mm² and a coil diameter of about 200 to 450 mm, and it is wound around the outer peripheral side of the process chamber 202 about 2 to 60 times. The high-frequency resonant coil 206 is supported on plural supports. These supports are made of an insulating material, such as resin, in the shape of a plate and provided to stand vertically on the top end face of the flange 218.

The high-frequency resonant coil 206 is connected to an external shield 220 described below at one or the both ends thereof via a matching capacitor (not shown) in a resonant mode. For resonance of the high-frequency resonant coil 206, a resonant mode at a ¼ wavelength or ½ wavelength is selected. Further, a tap for establishing a connection to the high-frequency power supply 207 is provided to the high-frequency resonant coil 206. The position at which the tap is provided can be adjusted in such a manner that the resonant characteristics of the high-frequency coil 206 and the high-frequency power supply 207 become almost equal to each other. The high-frequency power supply 207 has a high-frequency wave generator 207a and an amplifier 207b, and it is configured to supply about 1 to 5 KW of radio frequency power at about 1 to 100 MHz. It is thus configured in such a manner that a gas inside the process chamber 202 is excited by the magnetic field component of the high-frequency resonant coil 206.

The external shield 220 is formed of a conducting member, for example, aluminum, in a cylindrical shape. It is provided on the outer peripheral side of the high-frequency resonant coil 206 and one end thereof is electrically grounded. It is thus configured so as to shield an electric field generated by the high-frequency resonant coil 206.

A shield member 222 is provided between the high-frequency resonant coil 206 and the process chamber 202 so as to shield the electric field component of the high-frequency resonant coil 206. The shield member 222 is made of a conducting material, such as aluminum, in a cylindrical shape, and has a diameter large enough to be disposed concentrically with the process chamber 202 while being spaced apart by a specific interval from the outer peripheral surface of the process chamber 202. It is mounted on the end face of the flange 218 and locked on the upper lid side of the external shield 220. The shield member 222 is provided with plural slits that are parallel to the axial line thereof. These slits are formed of clearances about 2 to 10 mm wide and made in the circumferential direction of the shield member 222 at a pitch of about 5 to 100 mm. The shield member 222 is electrically grounded via the external shield 220.

The processing chamber 208 is formed in a short bottomed almost cylindrical shape, and it is suspended from the lower surface of the horizontal base of the frame 216. The processing chamber 208 is provided so as to continue to the open bottom surface of the process chamber 202 via a first opening 216a made in the frame 216 and a second opening 208a made in the top plate of the processing chamber 208. A gate valve 224 is provided on the peripheral surface of the processing chamber 208, and a wafer 214 is carried in and carried out via the gate valve 224. In addition, an emission intensity measuring instrument 215 is provided at part of the side wall of the processing chamber 208 to detect (measure) emission intensity of a plasma generated inside the processing chamber 208.

The emission intensity measuring instrument 215 is capable of detecting the end point more precisely by detecting the wafer 214 from directly above. It is therefore preferable that the emission intensity measuring instrument 215 is provided between the chamber lower portion and the wafer holder 210 in the height direction. It is further preferable that the emission intensity measuring instrument 215 is provided at the level as high as the wafer 214. This is because the emission intensity measuring instrument 215, being provided at the level as high as the wafer 214, is capable of detecting a processing state of the wafer 214 in a more reliable manner.

The wafer holder 210 is formed in the shape of a short column, and is formed of a holder block (susceptor) 210a on the upper end face of which the wafer 214 is mounted, and a supporting column 210b that supports the holder block 210a. The holder block 210a is provided with an electromagnetic chuck that is normally used. The supporting column 210b is provided to stand on a stay 226 described below so as to be inserted through the second opening 208a made in the bottom plate of the processing chamber 208 in a slidable manner. The stay 226 is configured in such a manner that it can be moved up or down by a ball screw 228 attached to driving means (not shown), such as a servo motor, that can rotate forward and backward. The holder block 210a is configured in such a manner that it can move up and down between the interior of the processing chamber 208 and a position almost at the bottom surface of the process chamber 202 through the second opening 208a and the first opening 216a. Also, a bellows that can contract and expand to shield the interior of the processing chamber 208 from the exterior is provided between the lower end surface of the holder block 210a and the bottom plate of the processing chamber 208.

It is sufficient that the gas discharge channels 212 are connected to the processing chamber 208 below the wafer holder 210, and for instance, they are connected to the bottom plate of the processing chamber 208. An exhaust system including a vacuum pump 213 is connected to the gas discharge channels 212. It is therefore possible to reduce the pressure in the interiors of the process chamber 202 and the processing chamber 208 via holes 208b made in the bottom plate of the processing chamber 208 and the gas discharge channels 212.

As is shown in FIG. 3, a porous plate 230 is disposed on the outer peripheral side of the wafer holder 210 in the processing chamber 208 so as to divide the processing chamber 208 to the upper and lower halves. Holes 230a opened in the porous plate 230 are formed to have a diameter of about 3 to 30 mm and disposed at almost equal intervals along the circumferential direction of the wafer holder 210. In a case where the porous plate 230 is disposed, it is possible to diffuse the flow of radicals to be sucked into the gas discharge channels 212 uniformly, which in turn makes it possible to ash the resist on the surface of the wafer 214 more uniformly.

The controller 232 is used as control means for controlling operations of various members that together form the ashing processing apparatus 200.

Processes by the substrate processing apparatus 100 and the ashing processing apparatus 200 will be described.

Unprocessed wafers (on which the resist is applied) are transported to the substrate processing apparatus 100 in which processing steps are carried out by the RGV while 25 wafers are accommodated in the pod 126. The pod 126 that has been transported is delivered from the RGV and mounted on the IO stage 124. The cap of the pod 126 is then opened by the pod opener.

When the pod 126 is opened, the second wafer transfer machine 118 installed in the second transfer chamber 116 picks up one of the wafers from the pod 126 and carries it in the first load lock chamber 108 to mount it on the substrate platform 112. During this transfer operation, the gate valve on the first transfer chamber 102 side is closed to maintain a negative pressure in the first transfer chamber 102. When the transfer of the wafer onto the substrate platform 112 is completed, the gate valve is closed and air is discharged from the first load lock chamber 108 until the pressure therein reaches a negative pressure.

When the pressure in the first load lock chamber 108 is reduced to a pre-set pressure value, the gate valve is opened. The first load lock chamber 108, the first transfer chamber 102, and the process chamber 202 are thus brought into communication with one another. Subsequently, the first wafer transfer machine 106 in the first transfer chamber 102 picks up the wafer from the substrate platform 112 and carries it onto the wafer holder 210 in the process chamber 202. Subsequently, a process gas is supplied inside the process chamber 202 to perform a desired process on the wafer. The process in the process chamber 202 will be described further below.

When the process in the process chamber 202 is completed, the processed wafer is carried out to the first transfer chamber by the first wafer transfer machine 106 in the first transfer chamber 102. The first wafer transfer machine 106 transports the wafer carried out from the process chamber 202 into the second load lock chamber 110 and places it on the substrate platform 114, after which the second load lock chamber 110 is closed by the gate valve.

When the second load lock chamber 110 is closed by the gate valve, the interior of the second load lock chamber 110 is restored to atmospheric pressure by an inert gas. When the interior of the second load lock chamber 110 has been restored almost to atmospheric pressure, the gate valve is opened and the cap of the empty pod 126 mounted on the IO stage 124 is opened by the pod opener. Subsequently, the second wafer transfer machine 118 in the second transfer chamber 116 picks up the wafer from the substrate platform 114 to carry it out to the second transfer chamber 116 and puts it in the pod 126 so as to be accommodated therein. As the operations described above are repeated, the wafers are processed successively by the substrate processing apparatus 100.

When the 25 processed wafers have been accommodated in the pod 126, the cap of the pod 126 is closed by the pod opener. The closed pod 126 is then transferred from the IO stage 124 to the next step by the RGV.

The process in the process chamber 202 of the ashing processing apparatus 200 of the invention will now be described further.

Herein, the process in the process chamber 202 as the first process furnace will be described for concrete and clear descriptions. It should be noted, however, that the same applies to processes in the other process furnaces in the substrate processing apparatus 100.

When a wafer 214 on which the resist is applied is carried in the processing chamber 208 and held on the wafer holder 210, gas remained the processing chamber is discharged via the gas discharge channels 212 by the driving of the vacuum pump 213. The pressure in the interiors of the process chamber 202 and the processing chamber 208 is thus reduced to a pressure of about 10 to 200 mTorr.

Subsequently, the gas supply device 203 and the high-frequency power supply 207 are activated. To be more concrete, a flow rate from the gas supply sources (not shown) is adjusted by the MFCs 203a while a quantity of discharged the remained gas is adjusted by the vacuum pump 213, so that a process gas for plasma generation, such as oxygen (O₂), is supplied inside the process chamber 202 from the gas supply device 203 while maintaining the vacuum inside the process chamber 202 at a pressure of, for example, about 50 mTorr to 10 Torr. Subsequently, radio frequency power is applied to the high-frequency resonant coil 206 by the high-frequency power supply 207 to generate an electric field and a magnetic field around the high-frequency resonant coil 206.

In this instance, the electric field component of the high-frequency resonant coil 206 is shielded by the shield member 222 provided between the high-frequency resonant coil 206 and the process chamber 202, so that the electric field component is applied to the process chamber 202 in the axial direction thereof. A process gas supplied inside the process chamber 202 is thus turned into plasma. In this instance, emission intensity of a plasma generated inside the processing chamber 208 is measured by the emission intensity measuring instrument 215 provided at part of the side wall of the processing chamber 208. When the controller 232 determines that all the resist on the wafer 214 is removed (ashed), it terminates the ashing process. The processed wafer 214 is carried out from the processing chamber 208 via the gate valve by the first wafer transfer machine 106.

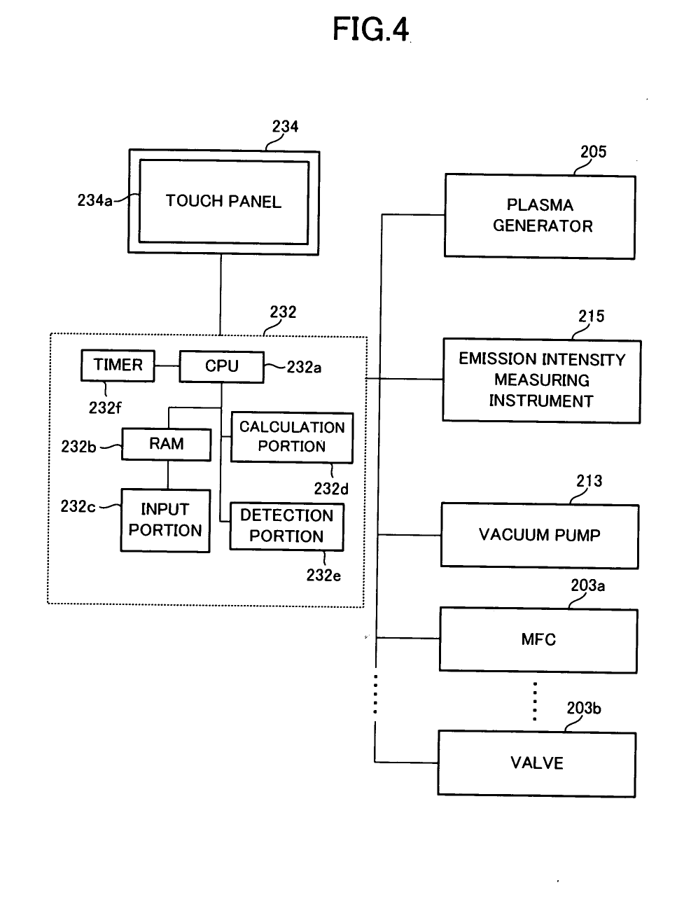

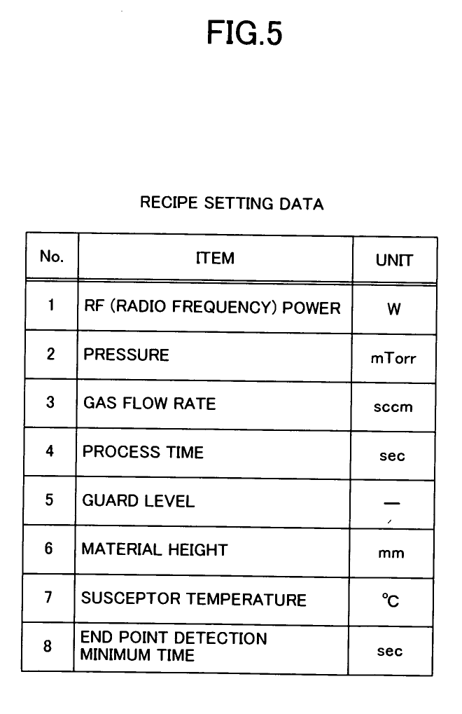

The functional configuration of the controller 232 will now be described on the basis of FIG. 4 and FIG. 5.

The controller 232 is connected to the plasma generator 205, the emission intensity measuring instrument 215, the vacuum pump 213, the MFCs 203a, the valves 203b, a touch panel 234 as input display part, and so forth. It is configured to receive measurement data outputted from the emission intensity measuring instrument 215 and to control operations of the plasma generator 205, the vacuum pump 213, the MFCs 203a, the valves 203b, and the touch panel 234.

The touch panel 234 has a display screen 234a and is configured to accept an input instruction, such as recipe setting data, from the operator. As is shown in FIG. 5, the touch panel 234 accepts recipe setting data, such as an RF (Radio Frequency) power value (W), a pressure value (mTorr), a gas flow rate value (sccm) of a gas to be supplied, a process time (sec), a guard level described below, a height of a material (mm), a temperature of a susceptor (° C.), and an end point detection minimum time (sec) as a predetermined time. The touch panel 234 is configured to output the recipe setting data thus inputted by the operator to the controller 232, and to display data or the like outputted from the controller 232 on the display screen 234a.

A method of detecting the end point by the controller 232 will now be described on the basis of FIG. 4 and FIG. 5.

As is shown in FIG. 4, the controller 232 has a CPU 232a, a RAM 232b, an input portion 232c, a calculation portion 232d, and a detection portion 232e. The CPU 232 a controls operations of the overall apparatus. The RAM 232b stores therein data outputted from the emission intensity measuring instrument 215 and recipe setting data outputted from the touch panel 234, both of which are inputted therein via the input portion 232c. The calculation portion 232d is configured to calculate an amount of variance in emission intensity on the basis of data stored in the RAM 232b, and the detection portion 232e is configured to detect an end point described below on the basis of the result (amount of variance in emission intensity) calculated by the calculation portion 232d. A timer 232f counts the process time or the like.

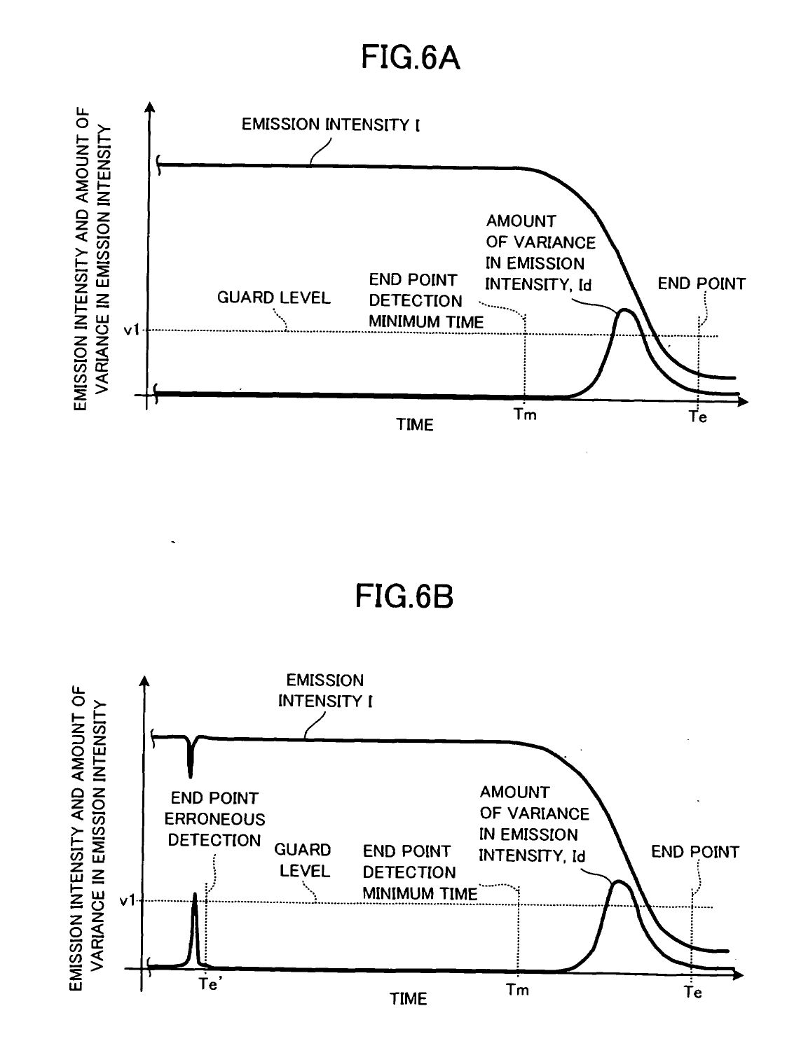

To be more concrete, as is shown in FIG. 6A, the calculation portion 232d calculates an amount of variance in emission intensity, Id, on the basis of emission intensity I inputted therein via the input portion 232c at every predetermined time. The detection portion 232e makes a comparison between the amount of variance in emission intensity Id, calculated by the calculation portion 232d and a guard level v1 pre-stored in the RAM 232b. The timer 232f counts the process time at timing when the amount of variance in emission intensity Id, reaches an almost constant level after the amount of variance in emission intensity Id, becomes larger than the guard level v1, and the detection portion 232e is configured to detect this time as an end point Te.

In this instance, the controller 232 makes a comparison between the end point Te and the end point detection minimum time Tm pre-stored in the RAM 232b, and terminates the ashing process in a case where the end point Te is found to have passed the end point detection minimum time Tm (Te>Tm). Meanwhile, as is shown in FIG. 6B, in a case where an end point Te′ is found not to have passed the end point detection minimum time Tm (Te′<Tm), the controller 232 is configured to determine that the end point Te′ is an early erroneous detection and to display a message indicating this determination on the display screen 234a of the touch panel 234. By displaying the message, the operator is able to know an early erroneous detection state in a reliable manner.

The guard level v1 and the end point detection minimum point Tm are set in advance by the operator. They are stored (saved) in the RAM 232b via the touch panel or stored (saved) in the RAM 232b by being included in a recipe or the like in advance.

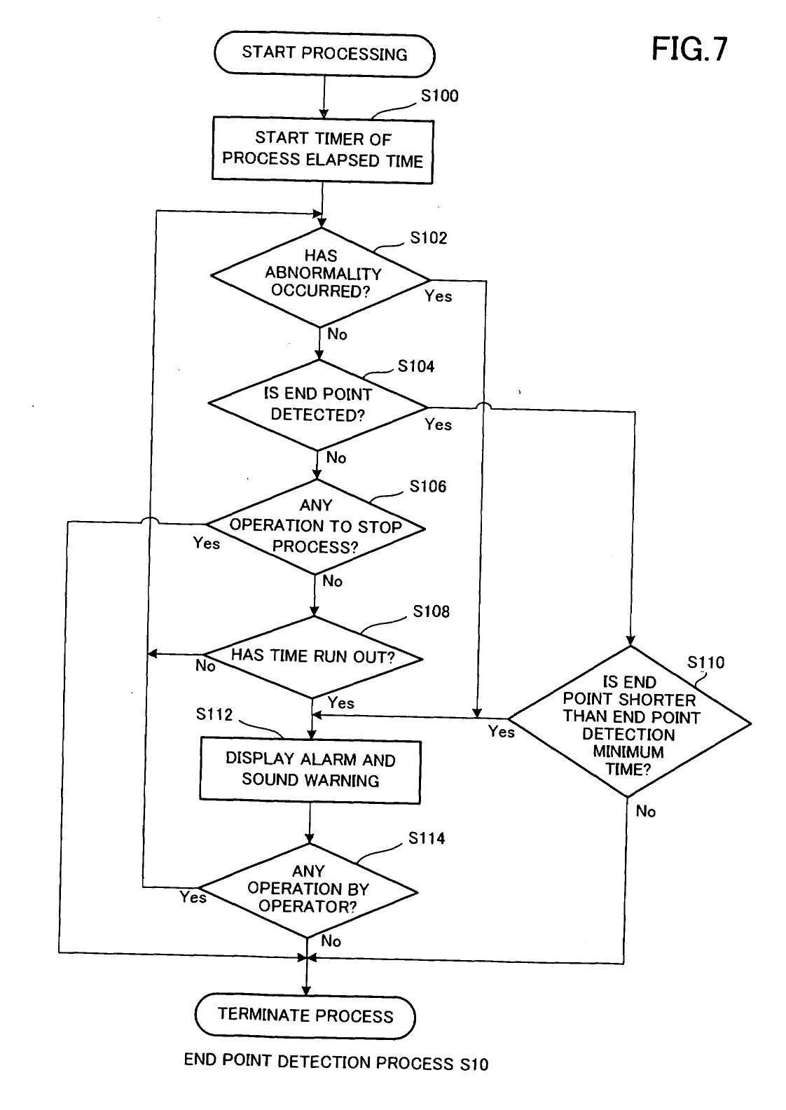

An end point detection process S10 will now be described on the basis of FIG. 7.

In Step S100, when the ashing process on the wafer 214 is started, the controller 232 starts to count the process elapsed time by means of the timer 232f (starts a timer of a process elapsed time). Subsequently, as is shown in FIG. 6, the emission intensity measuring instrument 215 detects emission intensity of a plasma generated inside the processing chamber 208. In this instance, the controller 232 stores the emission intensity I of the plasma detected by the emission intensity measuring instrument 215 into the RAM 232b. Further, the calculation portion 232d of the controller 232 calculates the amount of variance in emission intensity Id, on the basis of the emission intensity I thus detected.

In Step S102, the controller 232 determines whether an abnormality has occurred in the ashing process. In a case where it determines the absence of an abnormality, it proceeds to the processing in Step S104. In a case where it determines the occurrence of an abnormality, it proceeds to the processing in Step S112.

In Step S104, the controller 232 determines whether the end point is detected. To be more concrete, as is shown in FIG. 6, the detection portion 232e of the controller 232 makes a comparison between the amount of variance in emission intensity Id, calculated in the calculation portion 232d and the guard level v1, and detects, as the end point Te, the timing at which the amount of variance in emission intensity Id, reaches an almost constant level after the amount of variance in emission intensity Id, becomes larger than the guard level v1. In a case where the end point is detected by the detection portion 232e, the controller 232 proceeds to the processing in Step S110. In a case where it determines that the end point is not detected, it proceeds to the processing in Step S106.

In Step S106, the controller 232 determines whether a stop operation is performed. In a case where it determines that the stop operation is not performed, it proceeds to the processing in Step S108. Meanwhile, in a case where, for example, a process stop button on the touch panel 234 is depressed by the operator, the controller 232 determines that a stop operation is performed and terminates the process.

In Step S108, the controller 232 determines whether the time has run out. To be more concrete, the controller 232 determines whether the value of the timer of the process elapsed time has becomes larger than the pre-set value for the process time. In a case where it determines that the former has become larger than the latter (time has run out), it proceeds to the processing in Step S110. In a case where it determines that the time has not run out, it returns to the processing in Step S102 again.

In Step S110, the controller 232 determines whether the end point is shorter than the end point detection minimum time. To be more concrete, as is shown in FIG. 6B, the controller 232 makes a comparison between the end point detected by the detection portion 232e (for example, the end point Te′) and the pre-set end point detection minimum time Tm. In a case where the end point Te′ is found not to have passed the end point detection minimum time Tm (Te′<Tm), it proceeds to the processing in Step S112. Meanwhile, in a case where the controller 232 determines that the end point detected by the detection portion 232e (for example, the end point Te) has passed the pre-set end point detection minimum time Tm (Tm<Te), it determines that all the resist on the wafer 214 has been ashed and terminates the ashing process.

Herein, the phrase, “terminate the ashing process”, means to stop the plasma generator 205. In short, power from the high-frequency power supply 207 to the high-frequency resonant coil 206 is stopped. Also, a supply of the process gas is stopped at the same time when the power is stopped.

In Step S112, the controller 232 displays the result of the comparison between the end point and the end point detection minimum time, that is, an alarm indicating that the end point was erroneously detected, on the display screen 234a of the touch panel 234 or by means of an alarm lamp. Alternatively, a warning buzzer may be sounded together with the display of an alarm. In particular, in the case of the detection of an abnormality, by sounding the warning buzzer together with the display showing an abnormal state, it is possible to inform the operator of the abnormal state in a reliable manner. Thereafter, the controller 232 proceeds to the processing in Step S114.

In Step S114, the controller 232 determines whether the operator has made any operation. To be more concrete, in a case where an instruction to continue the process is inputted from the operator by an operation on the touch panel 234 or the like, the controller 232 returns to the processing in Step S102 again. In a case where the operator has not made any operation or the operator has inputted an instruction to stop the process, it terminates the process.

According to the substrate processing method of the invention, because it has the making a comparison between the detected end point and the end point detection minimum time and the displaying the result of the comparison, the end point can be confirmed precisely. It is thus possible to achieve enhancement in productivity by preventing the process from being terminated due to an erroneous detection of the endpoint.

In the embodiment described above, the amount of variance in emission intensity Id, is detected first, and then whether the detected end point Te is shorter than the detection minimum time Tm is determined. The invention, however, is not limited to this configuration. For instance, whether the process time has passed the detection minimum time Tm may be confirmed first. After it is determined that the process time has passed the detection minimum time, the amount of variance in emission intensity Id, may be detected so as to determine that the resist has been ashed when the amount of variance in emission intensity Id, becomes a constant state after it exceeds the guard level, that is, upon detection of the end point Te.

In this case, the emission intensity measuring instrument 215 may be activated when the process is started. However, it may be activated when the process detection minimum time Tm approaches to detect emission intensity. By being activated when the process detection minimum time Tm approaches in this manner, power can be saved. In addition, because the amount of variance in emission intensity is detected for the first time when the process detection minimum time Tm approaches, the load can be lessened in comparison with a case where the amount of variance is detected constantly.

The display portion is capable of displaying an indication other than an alarm. For example, it may display the process time since the substrate is carried in after a plasma process is started. Alternatively, it may display the process detection minimum time Tm. These displays enable the operator to know an elapsed time of the ashing process. Further, these displays enable the operator to know that the end of the ashing process is approaching.

Hereinafter, preferred examples of the invention will be described.

### EXAMPLE 1

A substrate processing method includes: detecting emission intensity; calculating an amount of variance in emission intensity that has been detected; detecting an end point from the calculated amount of variance in emission intensity; making a comparison between the detected end point and a predetermined time; and displaying a result of the comparison. According to this example, the end point of the substrate process can be confirmed precisely. It is thus possible to achieve enhancement in productivity by preventing the process from being terminated due to an erroneous detection of the end point.

### EXAMPLE 2

The substrate processing method of Example 1 further includes a terminating ashing process by stopping a supply of power from a high-frequency power supply in a case where the comparison is made between the end point and the predetermined time and the end point is found to have passed the predetermined time. According to this example, the endpoint of the substrate process can be confirmed precisely. It is thus possible to terminate the ashing process in a reliable manner after the end point is confirmed.

### EXAMPLE 3

A substrate processing method includes: detecting emission intensity; calculating an amount of variance in emission intensity that has been detected; reading a process time when the amount of variance in emission intensity becomes constant after the amount of variance in emission intensity is determined as being larger than the emission intensity and a guard level pre-stored in a storage portion; making a comparison between the process time and a detection minimum time pre-stored in the storage portion; and terminating an ashing process when the process time is found to have passed the detection minimum time. According to this example, by making comparisons with the pre-stored guard level and detection minimum detection time, it is possible to perform the control as the operator desires in a reliable manner. In addition, because the amount of variance in emission intensity is detected before the process time reaches the detection minimum time, once the processing is started, an erroneous detection can be known in a reliable manner at any time.

### EXAMPLE 4

A substrate processing method includes: determining whether a process time has passed a detection minimum time by counting the process time; detecting emission intensity when the process time is found to have passed the detection minimum time; calculating an amount of variance in emission intensity that has been detected; and terminating an ashing process when the amount of variance in emission intensity becomes constant after the emission intensity that has been detected is determined as being larger than a guard level pre-stored in a storage portion. According to this example, because the amount of variance in emission intensity is detected for the first time when the process detection minimum time Tm approaches, it is possible to lessen the load in comparison with a case where the amount of variance is detected constantly.

### EXAMPLE 5

The substrate processing method of Example 3 or 4 further includes displaying on a display portion a message indicating an erroneous detection when the process time is found not to have reached the detection minimum time after a comparison is made between the process time and the detection minimum time.

### EXAMPLE 6

A substrate processing method includes: carrying a substrate in a processing chamber and mounting the substrate on a substrate holder; generating a plasma after a process gas is supplied to the processing chamber; detecting emission intensity of the plasma that has been generated; calculating an amount of variance in emission intensity that has been detected; detecting an end point from the calculated amount of variance in emission intensity; making a comparison between the detected end point and a predetermined time; displaying a result of the comparison; and carrying the substrate out from the processing chamber after a plasma process is terminated. According to this example, the end point of the substrate process can be detected precisely. Because not only can the process be prevented from being terminated due to an erroneous detection of the end point, but also the processed substrate can be carried out in a reliable manner, it is possible to achieve enhancement in productivity.

### EXAMPLE 7

The substrate processing method of Example 6 further includes displaying a substrate process time on a display portion after generating the plasma. According to this example, the operator becomes able to know an elapsed time of the ashing process. Further, the operator is able to know that the end of the ashing process is approaching.

### EXAMPLE 8

A substrate processing method includes: carrying a substrate in a processing chamber and mounting the substrate on a substrate holder; generating a plasma by supplying an oxygen-containing gas; removing a resist by means of an oxygen plasma; detecting emission intensity of the oxygen plasma; calculating an amount of variance in emission intensity that has been detected; detecting an end point from the calculated amount of variance in emission intensity; making a comparison between the detected end point and a predetermined time; displaying a result of the comparison; and carrying the substrate out from the processing chamber after a plasma process is terminated. According to this example, the end point of the ashing process can be confirmed precisely. Because not only can the process be prevented from being terminated due to an erroneous detection of the end point, but also the processed substrate can be carried out in a reliable manner, it is possible to achieve enhancement in productivity.

### EXAMPLE 9

A substrate processing apparatus includes: a gas supply portion that supplies a process gas; a plasma generation portion that generates a plasma; a processing chamber in which a wafer mounted on a wafer holder is processed by means of the plasma; a display portion; a timer that counts a process time; an emission intensity measuring portion; and a control portion that makes a comparison between the amount of variance in emission intensity detected by the emission intensity measuring portion and a guard level pre-stored in a storage portion to read a process time when the amount of variance in emission intensity becomes constant after the amount of variance in emission intensity is determined as being larger than the guard level, and makes a comparison between the process time and a detection minimum time pre-stored in the storage portion to terminate a plasma process when the process time is found to have passed the detection minimum time. According to this example, the end point of the substrate processing can be confirmed precisely. Also, it is possible to achieve enhancement in productivity by preventing the process from being terminated due to an erroneous detection of the end point.

### EXAMPLE 10

The substrate processing apparatus of Example 9 is configured in such a manner that the display portion has a touch panel and an instruction from an operator is provided from the touch panel. According to this example, the operator becomes able to transmit information to the apparatus in a reliable manner by providing an instruction by means of the touch panel.

### EXAMPLE 11

The substrate processing apparatus of Example 10 is configured in such a manner that the gas to be supplied is an oxygen-containing gas. According to this example, the end point of the ashing process can be confirmed precisely. It is thus possible to achieve enhancement in productivity by preventing the process from being terminated due to an erroneous detection of the end point.

### EXAMPLE 12

The substrate processing apparatus of Example 9 is configured in such a manner that the display portion displays a result of the comparison between the process time and the detection minimum time. According to this example, by displaying the result of the comparison between the process time and the detection minimum time, the operator becomes able to know the current processing state in a reliable manner.

The invention can be used for the processing method of a substrate used in a semiconductor device or the like that needs to achieve enhancement in productivity.

1. A substrate processing method, comprising:
detecting emission intensity;
calculating an amount of variance in emission intensity that has been detected;
detecting an end point from the calculated amount of variance in emission intensity;
making a comparison between the detected end point and a predetermined time; and
displaying a result of the comparison.

2. The substrate processing method according to claim 1, further comprising:
terminating an ashing process by stopping a supply of power from a high-frequency power supply in a case where the comparison is made between the end point and the predetermined time and the end point is found to have passed the predetermined time.

3. A substrate processing method, comprising:
detecting emission intensity;
calculating an amount of variance in emission intensity that has been detected;
reading a process time when the amount of variance in emission intensity becomes constant after the amount of variance in emission intensity is determined as being larger than the emission intensity and a guard level pre-stored in a storage portion;
making a comparison between the process time and a detection minimum time pre-stored in the storage portion; and
terminating an ashing process when the process time is found to have passed the detection minimum time.

4. A substrate processing method, comprising:
determining whether a process time has passed a detection minimum time by counting the process time;
detecting emission intensity when the process time is found to have passed the detection minimum time;
calculating an amount of variance in emission intensity that has been detected; and
terminating an ashing process when the amount of variance in emission intensity becomes constant after the emission intensity that has been detected is determined as being larger than a guard level pre-stored in a storage portion.

5. The substrate processing method according to claim 3, further comprising:
displaying on a display portion a message indicating an erroneous detection when the process time is found not to have reached the detection minimum time after a comparison is made between the process time and the detection minimum time.

6. A substrate processing method, comprising:
carrying a substrate in a processing chamber and mounting the substrate on a substrate holder;
generating a plasma after a process gas is supplied to the processing chamber;
detecting emission intensity of the plasma that has been generated;
calculating an amount of variance in emission intensity that has been detected;
detecting an end point from the calculated amount of variance in emission intensity;
making a comparison between the detected end point and a predetermined time;
displaying a result of the comparison; and
carrying the substrate out from the processing chamber after a plasma process is terminated.

7. The substrate processing method according to claim 6, further comprising:
displaying a substrate process time on a display portion after generating the plasma.

8. A substrate processing method, comprising:
carrying a substrate in a processing chamber and mounting the substrate on a substrate holder;
generating a plasma by supplying an oxygen-containing gas;
removing a resist by means of an oxygen plasma;
detecting emission intensity of the oxygen plasma;
calculating an amount of variance in emission intensity that has been detected;
detecting an end point from the calculated amount of variance in emission intensity;
making a comparison between the detected end point and a predetermined time;
displaying a result of the comparison; and
carrying the substrate out from the processing chamber after a plasma process is terminated.

9. A substrate processing apparatus, comprising:
a gas supply portion that supplies a process gas;
a plasma generation portion that generates a plasma;
a processing chamber in which a wafer mounted on a wafer holder is processed by means of the plasma;
a display portion;
a timer that counts a process time;
an emission intensity measuring portion; and
a control portion that makes a comparison between the amount of variance in emission intensity detected by the emission intensity measuring portion and a guard level pre-stored in a storage portion to read a process time when the amount of variance in emission intensity becomes constant after the amount of variance in emission intensity is determined as being larger than the guard level, and makes a comparison between the process time and a detection minimum time pre-stored in the storage portion to terminate a plasma process when the process time is found to have passed the detection minimum time.

10. The substrate processing apparatus according to claim 9, wherein:
the display portion has a touch panel and an instruction from an operator is provided from the touch panel.

11. The substrate processing apparatus according to claim 10, wherein:
the gas to be supplied is an oxygen-containing gas.

12. The substrate processing apparatus according to claim 9, wherein:
the display portion displays a result of the comparison between the process time and the detection minimum time.

13. The substrate processing method according to claim 4, further comprising:
displaying on a display portion a message indicating an erroneous detection when the process time is found not to have reached the detection minimum time after a comparison is made between the process time and the detection minimum time.
